(19) United States
(12) Patent Application Publication
(10) Pub. No.: US 2017/0141261 A1
(43) Pub. Date: May 18, 2017

(54) Light Emitting Diodes and Fabrication Method

(71) Applicant: XIAMEN SANAN OPTOELECTRONICS TECHNOLOGY CO., LTD., Xiamen (CN)

(72) Inventors: Jinjian ZHENG, Xiamen (CN); Feilin XUN, Xiamen (CN); Mingyue WU, Xiamen (CN); Jiansen ZHENG, Xiamen (CN); Zhiming LI, Xiamen (CN); Weihua DU, Xiamen (CN); Heqing DENG, Xiamen (CN); Chilun CHOU, Xiamen (CN); Shuiqing LI, Xiamen (CN); Junyong KANG, Xiamen (CN)

(73) Assignee: XIAMEN SANAN OPTOELECTRONICS TECHNOLOGY CO., LTD., Xiamen (CN)

(21) Appl. No.: 15/418,708

(22) Filed: Jan. 28, 2017

Related U.S. Application Data
(63) Continuation of application No. PCT/CN2015/078569, filed on May 8, 2015.

(30) Foreign Application Priority Data
Nov. 27, 2014 (CN) 201410695296.3

(51) Int. Cl. H01L 33/06; H01L 33/00; H01L 33/12; H01L 33/10

(52) U.S. Cl. CPC H01L 33/06; H01L 33/10; H01L 33/0075; H01L 33/12; H01L 2933/0025

(57) ABSTRACT

A light emitting diode (LED) includes quantum dots serving as the quantum well layer in the multiple-quantum well (MQW) structure, which can greatly improve the combination efficiency of electrons and holes due to quantum confinement effect; a nanoscale metal reflective layer is formed between the quantum barrier layer with nanoscale pits to instantly reflect the light emitted downwards from the MQW to the front of epitaxial structure; in addition, the nanoscale metal reflective layer can form surface plasmon to further improve light emitting efficiency.

### CROSS-REFERENCE TO RELATED APPLICATIONS

The present application is a continuation of, and claims priority to, PCT/CN2015/078569, filed May 8, 2015, which claims priorities to Chinese Patent Application No. CN 201410695296.3, filed Nov. 27, 2014. The disclosures of the above applications are hereby incorporated by reference in their entirety.

### BACKGROUND

At present, light emitting diodes (LEDs) are applied in general lighting. However, due to low internal quantum efficiency (IQE), the luminous efficiency of LEDs is low, restricting LEDs from further occupying the market shares. To drive commercial application of white light LEDs, it is urgent to greatly improve luminous efficiency of LEDs. Though much attempt has been made to improve IQE, there is still long way to go.

In consideration of low luminous efficiency among the LEDs of existing art, it is necessary to put forward a new LED epitaxial structure and the fabrication method thereof.

### SUMMARY

The present disclosure relates to a LED epitaxial structure and the fabrication method thereof, wherein, quantum dots are as the quantum well layer in the light emitting layer MQW (multiple-quantum well) structure, which can greatly improve the combination efficiency of electrons and holes due to quantum confinement effect; at the same time, a nanoscale metal reflective layer is formed between the quantum barrier layer and the quantum well layer to instantly reflect the light emitted downwards from the MQW to the front of epitaxial structure; in addition, the nanoscale metal reflective layer can form surface plasmon to further improve light emitting efficiency.

According to the first aspect of the present disclosure, a light emitting diode is provided, comprising: a first-conductive type semiconductor layer, a light emitting layer MQW structure and a second-conductive type semiconductor layer on a substrate, wherein: the light emitting layer MQW structure comprises from bottom to up: a first quantum barrier layer with nanoscale pits, a nanoscale metal reflective layer on the pit surface, quantum dots on the metal reflective layer surface as a quantum well layer, and a second quantum barrier layer on the first quantum barrier layer, the metal reflective layer and the quantum dots.

According to the second aspect of the present disclosure, a light emitting diode is provided, comprising: a first-conductive type semiconductor layer, a light emitting layer MQW structure and a second-conductive type semiconductor layer on a substrate, wherein: the light emitting layer MQW structure comprises from bottom to up: a first quantum barrier layer with nanoscale pits, quantum dots filled in the pits as a quantum well layer, a nanoscale metal reflective layer on the quantum dot surface, and a second quantum barrier layer on the first quantum barrier layer, the metal reflective layer and the quantum dots.

Further, the nanoscale metal reflective layer is a laminated or a dotted layer.

Further, the metal reflective layer is made of Ag, Al or their combination.

Further, the nanoscale pits are in regular and uniform distribution.

Further, the first and the second-conductive type semiconductors are single-layer or multi-layer structures made of AlN, GaN, AlₓGa₁₋ₓN, In_{y}Ga_{1-y}N or (AlₓGa₁₋ₓ)_{1-y}In_{y}N, wherein, 0<x<1, 0<y<1.

According to the third aspect of the present disclosure, a fabrication method of light emitting diodes, comprising: providing a substrate; forming a first-conductive type semiconductor layer, a light emitting layer MQW structure and a second-conductive type semiconductor layer in sequence on the substrate through epitaxial growth, wherein: the light emitting layer MQW structure is formed by: forming a first quantum barrier layer on the first-conductive type semiconductor layer through epitaxial growth; forming nanoscale pits on the first quantum barrier layer through corrosion; filling a nanoscale metal reflective layer on the nanoscale pit surface; forming quantum dots on the nanoscale metal reflective layer surface as a quantum well layer through epitaxial growth; and forming a second quantum barrier layer through epitaxial growth, which covers on the first quantum barrier layer, the metal reflective layer and the quantum dots.

According to the fourth aspect of the present disclosure, a fabrication method of light emitting diodes, comprising: providing a substrate; forming a first-conductive type semiconductor layer, a light emitting layer MQW structure and a second-conductive type semiconductor layer in sequence on the substrate through epitaxial growth, wherein: the light emitting layer MQW structure is formed by: forming a first quantum barrier layer on the first-conductive type semiconductor layer through epitaxial growth; forming nanoscale pits on the first quantum barrier layer through corrosion; filling quantum dots in the pits as a quantum well layer; forming a nanoscale metal reflective layer on the quantum dot surface; and forming a second quantum barrier layer through epitaxial growth, which covers on the first quantum barrier layer, the metal reflective layer and the quantum dots.

Further, the first quantum barrier layer is formed through epitaxial growth by inputting mixed gas sources of TEGa, NH₃ and N₂, wherein, the growth temperature is 750-900° C., preferably 850° C.; the pressure is 50-500 Torr, and preferably 200 Torr; and the thickness is 1-50 nm, and preferably 10 nm.

Further, the nanoscale pits of the first quantum barrier layer are formed by: raising temperature to 1,000-1,200° C., closing gas sources of TEGa, NH₃ and N₂, and inputting H₂ to make the surface of the first quantum barrier layer into nanoscale pits through decomposition and corrosion.

Further, the nanoscale metal reflective layer is formed by: controlling the growth temperature at 700-900° C. and preferably 850° C.; closing H₂, N₂ and NH₃, and inputting TMAl sources; and making the metal reflective layer completely cover the nanoscale pits through annealing, wherein, the metal reflective layer is 1-10 nm thick, and preferably 2 nm.

Further, the quantum dots are formed on the nanoscale metal reflective layer surface through epitaxial growth by: controlling the growth temperature below 750° C.; closing TMAl source and inputting N₂, NH₃, TEGa and TMIn sources.

Further, the second quantum barrier layer is formed by: inputting TEGa source, NH₃ and N₂; controlling growth direction as three-dimensional growth, wherein, the growth temperature is 750-900° C., preferably 750° C.; the pressure is 200-500 Torr, and preferably 300 Torr; the growth time is 1-5 minute(s), and preferably 1 minute; and the pressure is 50-300 Torr, and preferably 200 Torr; or controlling the growth direction as two-dimensional growth to make the layer cover on the first quantum barrier layer, the metal reflective layer and the quantum dots through epitaxial lateral overgrown (ELOG) to completely level up the quantum dots, wherein, the growth temperature is 800-950° C., preferably 850° C.;

Further, the first and the second-conductive type semiconductors are single-layer or multi-layer structures made of AlN, GaN, AlₓGa₁₋ₓN, AlₓIn₁₋ₓN, In_{y}Ga_{1-y}N or (AlₓGa₁₋ₓ)_{1-y}In_{y}N, wherein, 0<x<1, 0<y<1.

In addition, except MOCVD, MBE or HVPE, other epitaxial growth methods are also available.

In another aspect, a light-emitting system is provided including a plurality of the LEDs described above. The light-emitting system can be used, for example, for lighting, display, signage, etc.

### BRIEF DESCRIPTION OF THE DRAWINGS

FIG. 1 is a schematic diagram of a LED epitaxial structure of Embodiment 1.

FIG. 2 is an enlarged view of the light emitting layer MQW structure as shown in FIG. 1.

FIG. 3 is a schematic diagram of gas source flows corresponding to the light emitting layer MQW structure as shown in FIG. 2.

FIG. 4 is an enlarged view of the light emitting layer MQW structure of the epitaxial structure of Embodiment 2.

FIG. 5 is an enlarged view of the light emitting layer MQW structure of the epitaxial structure of Embodiment 3.

In the drawings: 101: substrate; 102: buffer layer; 103: N—GaN layer; 104a: first GaN quantum barrier layer with nanoscale pits; 104b: metal reflective layer; 104c: InGaN quantum dots (quantum well layer); 104d: second GaN quantum barrier layer; 105: P—AlGaN electron blocking layer; 106: P—GaN layer; 107: P—InGaN high-doped P-type contact layer.

### DETAILED DESCRIPTION

### Embodiment 1

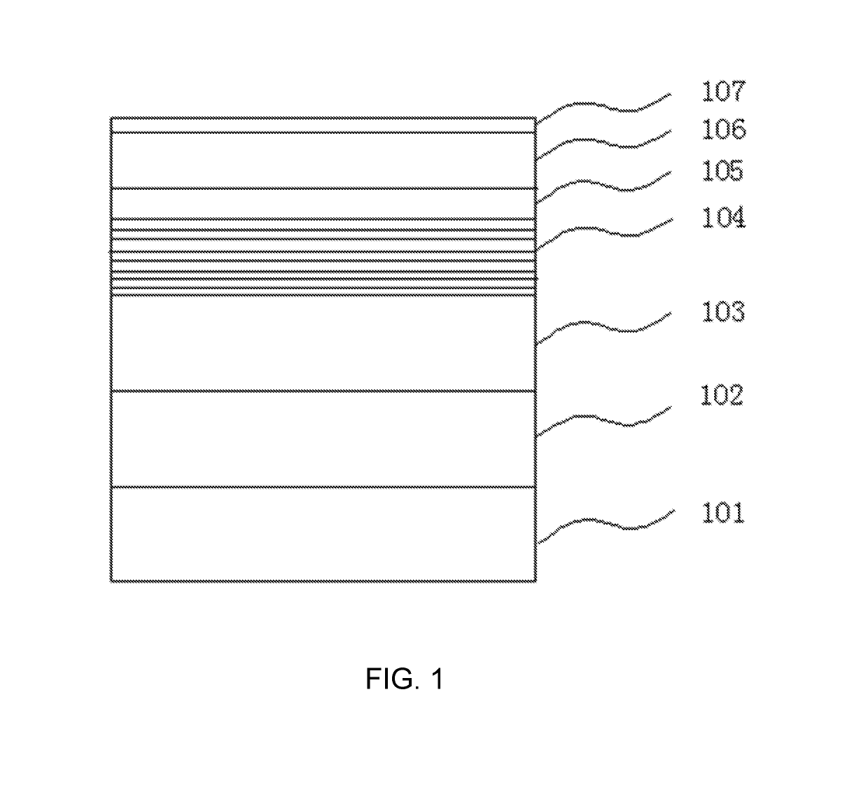

FIG. 1 is a schematic diagram of a LED epitaxial structure according to the present embodiment. As shown in FIG. 1, a LED epitaxial structure, comprising: a substrate 101 made of sapphire at bottom; an AlN buffer layer 102 on the substrate 101; a first-conductive type semiconductor layer, a light emitting layer MQW structure and a second-conductive type semiconductor layer on the AlN buffer layer 102, wherein, the first-conductive type semiconductor layer is an N-type semiconductor layer, and the second-conductive type semiconductor layer is a P-type semiconductor layer; the N-type semiconductor layer can be a single-layer or multi-layer structure composed of N-type AlN, GaN, AlₓGa₁₋ₓN, AlₓIn₁₋ₓN, In_{y}Ga_{1-y}N or (AlₓGa₁₋ₓ)_{1-y}In_{y}N, where, 0<x<1, 0<y<1; in this embodiment, preferably, the first-conductive type semiconductor layer is an N—GaN single-layer structure and the p-type semiconductor layer can be a single-layer or multi-layer structure composed of P-type AlN, GaN, AlₓGa₁₋ₓN, AlₓIn₁₋ₓN, In_{y}Ga_{1-y}N or (AlₓGa₁₋ₓ)_{1-y}In_{y}N, where, 0<x<1, 0<y<1; and preferably, in this embodiment, the second-conductive type semiconductor layer is a multi-layer structure composed of a P—AlGaN electron blocking layer, a P—GaN layer and a P—InGaN high-doped P-type contact layer.

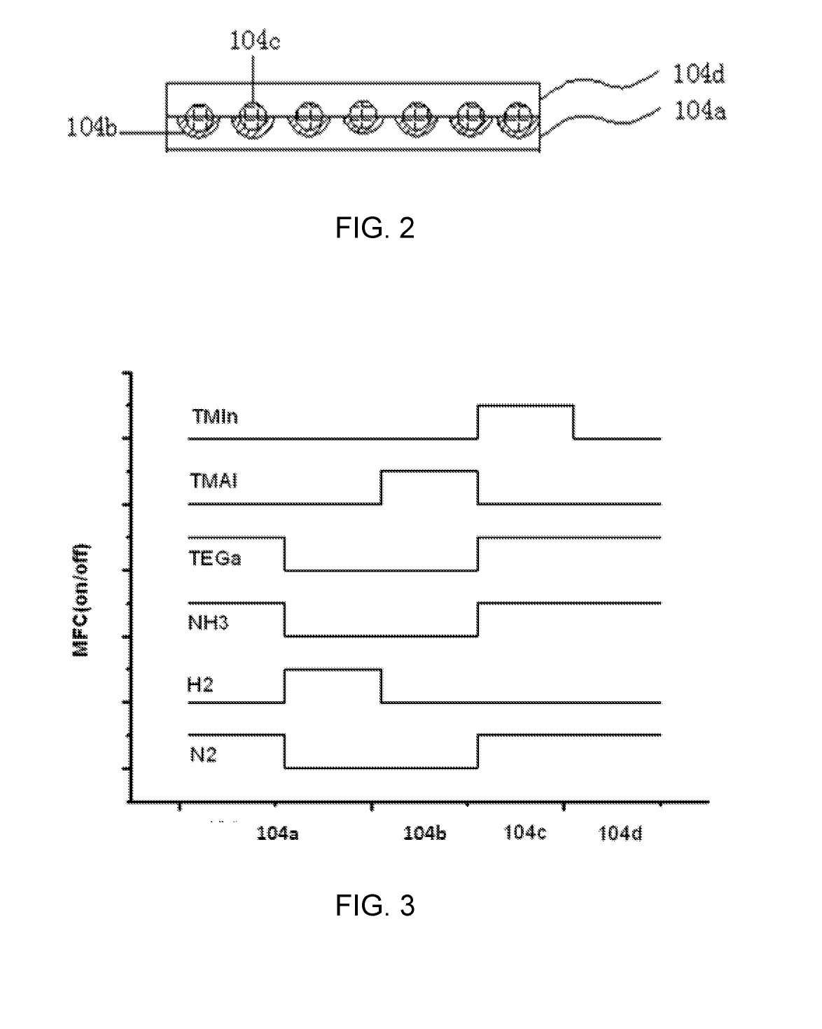

As shown in FIG. 2, the light emitting layer MQW structure of this embodiment comprises from bottom to up: a first quantum barrier layer 104a with nanoscale pits, a nanoscale laminated metal reflective layer 104b on the pit surface, quantum dots 104c on the metal reflective layer 104b surface as a quantum well layer, and a second quantum barrier layer 104d on the first quantum barrier layer 104a, the metal reflective layer 104b and the quantum dots 104c. In this embodiment, preferably, the quantum barrier layer is made of GaN; the quantum well layer is made of InGaN material; and the metal reflective layer is made of Ag or Al or their combination, preferably, Ag; the nanoscale pits are in random distribution or regular distribution, and preferably in this embodiment, the nanoscale pits are in regular and uniform distribution.

The present disclosure will be described in detail taking MOCVD epitaxial growth as example.

As shown in FIGS. 1-2, provide a patterned substrate 101 made of sapphire;

place the substrate 101 in MOCVD equipment (not shown), and grow an AlN buffer layer 102 on the substrate 101;

form a first-conductive type semiconductor layer, a light emitting layer MQW structure and a second-conductive type semiconductor layer on the buffer layer 102 through epitaxial growth, wherein: the light emitting layer MQW structure is formed by:

(1) forming a first quantum barrier layer on the first-conductive type semiconductor layer through epitaxial growth;

(2) forming nanoscale pits on the first quantum barrier layer through corrosion;

(3) filling a nanoscale metal reflective layer on the nanoscale pit surface;

(4) forming quantum dots on the nanoscale metal reflective layer surface as a quantum well layer through epitaxial growth; and

(5) forming a second quantum barrier layer through epitaxial growth, which covers on the first quantum barrier layer, the metal reflective layer and the quantum dots.

The growth method of the light emitting layer MQW structure will be described in detail in combination with FIG. 3.

In MOCVD equipment, common Al source and N source are TMAl and NH₃ respectively; and In source and Ga source are TMIn source and TEGa source respectively.

(1) Form a first GaN quantum barrier layer by inputting mixed gas source of TEGa, NH₃ and N₂ through epitaxial growth, wherein, the growth temperature is 880° C. and the thickness is 5 nm; rise temperature to 1,000-1,200° C., preferably 1,100° C.; close gas sources of TEGa, NH₃ and N₂, and input H₂ to make the surface of the first quantum barrier layer into nanoscale pits through decomposition and corrosion.

(2) Control the growth temperature at 750-900° C. and preferably 850° C.; close H₂, N₂ and NH₃, and input TMAl sources; and make the Al-laminated metal reflective layer 104b completely cover the nanoscale pits through annealing, wherein, the annealing time is 5-50 s and preferably 10 s; and the formed Al metal reflective layer is 1-10 nm thick, and preferably 2 nm.

(3) Reduce the growth temperature below 750° C., and preferably 700° C.; close TMAl source and input N₂, NH₃, TEGa and TMIn sources to obtain InGaN quantum dots 104c as an quantum well layer on the nanoscale metal reflective layer through epitaxial growth.

(4) Firstly input TEGa source, NH₃ and N₂; control growth direction as three-dimensional growth, wherein, the growth temperature is 750-900° C., preferably 750° C.; the pressure is 200-500 Torr, and preferably 300 Torr; the growth time is 1-5 minute(s), and preferably 1 minute; and the pressure is further reduced to 50-300 Torr, and preferably 200 Torr; or control the growth direction as two-dimensional growth to make the second GaN quantum barrier layer 104d cover on the first quantum barrier layer 104a, the Al metal reflective layer 104b and the InGaN quantum dots 104c through epitaxial lateral overgrown (ELOG) to completely level up the quantum dots 104c, which are good for further growth of the epitaxial layer in later processes, wherein, the growth temperature is 800-950° C., preferably 850° C.

(5) Follow the steps (1)-(4) for periodic growth of MQW by 1-50 times, preferably 8 times.

An LED epitaxial structure is therefore fabricated through the above process. In this structure, quantum dots serve as the quantum well layer in the multiple-quantum well (MQW) structure, which can greatly improve the combination efficiency of electrons and holes due to quantum confinement effect; at the same time, a nanoscale metal reflective layer is formed between the quantum barrier layer with nanoscale pits to instantly reflect the light emitted downwards from the MQW to the front of epitaxial structure; in addition, the nanoscale metal reflective layer can form surface plasmon to further improve light emitting efficiency.

### Embodiment 2

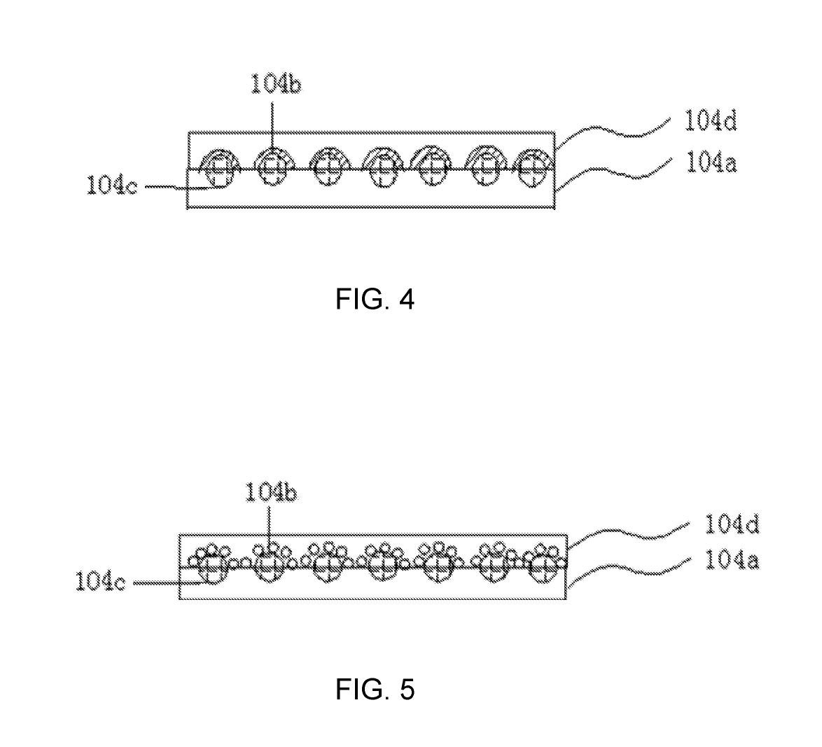

In Embodiment 1, firstly fill in a nanoscale laminated Al metal reflective layer 104b on the nanoscale pit surface and then form quantum dots 104c as a quantum well layer on the nanoscale metal reflective layer 104b surface through epitaxial growth. However, different from Embodiment 1, in this embodiment, as shown in FIG. 4, firstly fill in quantum dots 104c as a quantum well layer on the nanoscale pits and then form a nanoscale Al metal reflective layer 104b on the surface of quantum dots 104c, which can improve light reflectivity of the light emitting layer MQW structure and light emitting efficiency, making the LED epitaxial structures hence fabricated appropriate for normal-chip LEDs, vertical LEDs and flip-chip LEDs.

### Embodiment 3

As shown in FIG. 5, different from Embodiment 2, where the nanoscale Al metal reflective layer 104b is a laminated layer, in this embodiment, the layer is a dotted layer. Further, the dotted metal reflective layer is formed under the process conditions: after forming of the laminated Al metal reflective layer, raise the temperature to 1,000-1,100 ° C., preferably 1,100° C.; input H₂ to corrode the laminated Al metal reflective layer into a dotted layer (nano particle shape) to give full play of reflector and to form surface plasmon.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A light emitting diode (LED), comprising:
a first-conductive type semiconductor layer;
a light emitting layer multiple-quantum well (MQW) structure; and
a second-conductive type semiconductor layer;
wherein the light emitting layer MQW structure comprises:
a first quantum barrier layer with nanoscale pits;
a nanoscale metal reflective layer;
a plurality of quantum dots forming a quantum well layer; and
a second quantum barrier layer.

2. The LED of claim 1, wherein the nanoscale metal reflective layer is disposed over a surface of the nanoscale pits, the plurality of quantum dots are disposed over a surface of the metal reflective layer, and the second quantum barrier layer is disposed over the first quantum barrier layer, the metal reflective layer, and the quantum dots.

3. The LED of claim 2, wherein the nanoscale metal reflective layer is a laminated or a dotted layer.

4. The LED of claim 2, wherein the metal reflective layer comprises at least one of Ag or Al.

5. The LED of claim 2, wherein the nanoscale pits are in regular and uniform distribution.

6. The LED of claim 1, wherein the plurality of quantum dots are filled in the nanoscale pits, the nanoscale metal reflective layer is disposed over a surface of the plurality of quantum dots, and the second quantum barrier layer is disposed over the first quantum barrier layer, the metal reflective layer, and the plurality of quantum dots.

7. The LED of claim 6, wherein the nanoscale metal reflective layer is a laminated or a dotted layer.

8. The LED of claim 6, wherein the metal reflective layer comprises at least one of Ag or Al.

9. The LED of claim 6, wherein the nanoscale pits are in regular and uniform distribution.

10. A method of fabricating a light emitting diode (LED), the method comprising:
providing a substrate;
forming a first-conductive type semiconductor layer, a light emitting layer multiple quantum well (MQW) structure and a second-conductive type semiconductor layer in sequence over the substrate through epitaxial growth,
wherein the light emitting layer MQW structure is formed by:
forming a first quantum barrier layer over the first-conductive type semiconductor layer through epitaxial growth;
forming nanoscale pits over the first quantum barrier layer through corrosion;
forming a nanoscale metal reflective layer; forming a plurality of quantum dots as a quantum well layer through epitaxial growth; and
forming a second quantum barrier layer through epitaxial growth over the first quantum barrier layer, the metal reflective layer, and the quantum dots;
wherein the LED comprises:
the first conductive type semiconductor layer;
the light emitting layer multiple-quantum well (MQW) structure; and
the second conductive type semiconductor layer;
wherein the light emitting layer MQW structure comprises:
the first quantum barrier layer with nanoscale pits;
the nanoscale metal reflective layer;
the plurality of quantum dots forming a quantum well layer; and
the second quantum barrier layer.

11. The method of claim 10, wherein the nanoscale metal reflective layer is disposed over a surface of the nanoscale pits, the plurality of quantum dots are disposed over a surface of the metal reflective layer, and the second quantum barrier layer is disposed over the first quantum barrier layer, the metal reflective layer, and the quantum dots.

12. The method of claim 11, wherein the first quantum barrier layer is formed through epitaxial growth by inputting mixed gas sources of TEGa, NH₃ and N₂, wherein the growth temperature is 800-1,000° C.

13. The method of claim 11, wherein the nanoscale pits of the first quantum barrier layer are formed by: raising temperature to 1,000-1,200° C., closing gas sources of TEGa, NH₃ and N₂, and inputting H₂ to make the surface of the first quantum barrier layer into nanoscale pits through decomposition and corrosion.

14. The method of claim 11, wherein the metal reflective layer is formed by: controlling the growth temperature at 750-900° C.; closing H₂, N₂ and NH₃, and inputting TMAl sources; and making the metal reflective layer completely cover the nanoscale pits through annealing, wherein, the metal reflective layer is 1-10 nm thick.

15. The method of claim 11, wherein the quantum dots are formed on the nanoscale metal reflective layer surface through epitaxial growth by: controlling the growth temperature below 750° C.; closing TMAl source and inputting N₂, NH₃, TEGa and TMIn sources.

16. The method of claim 11, wherein the second quantum barrier layer is formed by: inputting TEGa source, NH₃ and N₂; controlling growth direction as three-dimensional growth, wherein, the growth temperature is 750-900° C.; the pressure is 200-500 Torr; the growth time is 1-5 minute(s); and the pressure is 50-300 Torr; or controlling the growth direction as two-dimensional growth to make the layer cover on the first quantum barrier layer, the metal reflective layer and the quantum dots through epitaxial lateral overgrown (ELOG) to completely level up the quantum dots, wherein, the growth temperature is 800-950° C.

17. The method of claim 10, wherein the nanoscale metal reflective layer is disposed over a surface of the nanoscale pits, the plurality of quantum dots are disposed over a surface of the metal reflective layer, and the second quantum barrier layer is disposed over the first quantum barrier layer, the metal reflective layer, and the quantum dots.

18. The method of claim 17, wherein:
the first quantum barrier layer is formed through epitaxial growth by inputting mixed gas sources of TEGa, NH₃ and N₂, wherein the growth temperature is 800-1,000° C.;
the nanoscale pits of the first quantum barrier layer are formed by: raising temperature to 1,000-1,200° C., closing gas sources of TEGa, NH₃ and N₂, and inputting H₂ to make the surface of the first quantum barrier layer into nanoscale pits through decomposition and corrosion;
wherein the metal reflective layer is formed by: controlling the growth temperature at 750-900° C.; closing H₂, N₂ and NH₃, and inputting TMAl sources; and making the metal reflective layer completely cover the nanoscale pits through annealing, wherein, the metal reflective layer is 1-10 nm thick;
wherein the quantum dots are formed on the nanoscale metal reflective layer surface through epitaxial growth by: controlling the growth temperature below 750° C.; closing TMAl source and inputting N₂, NH₃, TEGa and TMIn sources; and
the second quantum barrier layer is formed by: inputting TEGa source, NH₃ and N₂;
controlling growth direction as three-dimensional growth, wherein, the growth temperature is 750-900° C.; the pressure is 200-500 Torr; the growth time is 1-5 minute(s); and the pressure is 50-300 Torr; or controlling the growth direction as two-dimensional growth to make the layer cover on the first quantum barrier layer, the metal reflective layer and the quantum dots through epitaxial lateral overgrown (ELOG) to completely level up the quantum dots, wherein, the growth temperature is 800-950° C.

19. A light-emitting system comprising a plurality of light-emitting diodes (LEDs), each LED comprising:
a first-conductive type semiconductor layer;
a light emitting layer multiple-quantum well (MQW) structure; and
a second-conductive type semiconductor layer;
wherein the light emitting layer MQW structure comprises:
a first quantum barrier layer with nanoscale pits;
a nanoscale metal reflective layer;
a plurality of quantum dots forming a quantum well layer; and
a second quantum barrier layer.

20. The light-emitting system of claim 19, wherein the nanoscale metal reflective layer is disposed over a surface of the nanoscale pits, the plurality of quantum dots are disposed over a surface of the metal reflective layer, and the second quantum barrier layer is disposed over the first quantum barrier layer, the metal reflective layer, and the quantum dots.
